(19) United States
(12) Patent Application Publication
(10) Pub. No.: US 2022/0002142 A1
(43) Pub. Date: Jan. 6, 2022

(54) CAVITY SOI SUBSTRATE

(71) Applicant: Murata Manufacturing Co., Ltd., Nagaokakyo-shi (JP)

(72) Inventors: Makoto Sawamura, Nagaokakyo-shi (JP); Ryunosuke Hino, Nagaokakyo-shi (JP); Yutaka Kishimoto, Nagaokakyo-shi (JP)

(21) Appl. No.: 17/481,447

(22) Filed: Sep. 22, 2021

Related U.S. Application Data
(63) Continuation of application No. PCT/JP2020/012496, filed on Mar. 19, 2020.

(30) Foreign Application Priority Data
May 14, 2019 (JP) 2019-091300

(51) Int. Cl. B81B 1/00; B81C 1/00; B32B 3/30; B32B 3/26; B32B 9/04

(52) U.S. Cl. CPC B81B 1/00; B81C 1/00047; B32B 3/30; B32B 3/263; B32B 2457/00; B81B 2203/0315; B81C 2201/0132; B81C 2201/0133; B81C 2203/036; B32B 9/04

(57) ABSTRACT

A cavity SOI substrate that includes a first silicon substrate having a cavity; a second silicon substrate bonded to the first silicon substrate, wherein the second silicon substrate includes a first portion oppositely aligned with the cavity of the first silicon substrate and that is thicker than a second portion of the second silicon substrate that is bonded to the first silicon substrate; and a silicon oxide film interposed between the first silicon substrate and the second silicon substrate.

### CROSS REFERENCE TO RELATED APPLICATIONS

The present application is a continuation of International application No. PCT/JP2020/012496, filed Mar. 19, 2020, which claims priority to Japanese Patent Application No. 2019-091300, filed May 14, 2019, the entire contents of each of which are incorporated herein by reference.

### FIELD OF THE INVENTION

The present invention relates to a cavity SOI substrate (C-SOI substrate) which is used in a MEMS (Micro Electro Mechanical Systems) device, for example, and in which a first silicon substrate having a cavity and a second silicon substrate are bonded to each other with a silicon oxide film interposed therebetween.

### BACKGROUND OF THE INVENTION

In one known structure, a Silicon on Insulator (hereinafter called an “SOI”) layer on which a device, such as a movable component, is to be formed and a wafer serving as a support substrate for supporting the SOI layer are bonded to each other with an insulating layer interposed therebetween, the insulating layer including a cavity (see, for example, Patent Document 1).

In another known structure, a cavity is formed in one of two silicon substrates constituting a cavity SOI substrate, and a silicon oxide film (SiO₂) is formed in a bonded region between the two silicon substrates (see, for example, Patent Document 2).

Patent Document 1: Japanese Unexamined Patent Application Publication No. 2004-14461

Patent Document 2: Japanese Unexamined Patent Application Publication No. 2015-123547

### SUMMARY OF THE INVENTION

FIG. 8 is a schematic sectional view of a related-art cavity SOI substrate in which a second silicon substrate has substantially the same thickness in both a cavity-aligned portion and a bonded portion. In the related-art cavity SOI substrate 50, as illustrated in FIG. 8, a substrate with a uniform thickness is used as the second silicon substrate 58 that is bonded to a first silicon substrate 51 having a cavity 55. However, when the substrate with the uniform thickness is used as the second silicon substrate 58, the second silicon substrate 58 is recessed and displaced due to a difference in air pressure between the inside of the cavity 55 in a vacuum state and the outside of the cavity 55 under an atmospheric pressure. As a result, there arises a problem that flatness of the cavity SOI substrate (C-SOI substrate) 50 deteriorates and the yield of MEMS devices is reduced.

Another problem is that, when the first silicon substrate and the second silicon substrate are bonded to each other, cracks tend to generate in the first silicon substrate at an edge defining the cavity.

In consideration of the above-described situation, an object of the present invention is to provide a cavity SOI substrate that can suppress deterioration of flatness in a portion of a second silicon substrate, the portion being oppositely aligned with the cavity in a first silicon substrate.

The present invention provides a cavity SOI substrate that includes a first silicon substrate having a cavity; a second silicon substrate bonded to the first silicon substrate, wherein the second silicon substrate includes a first portion oppositely aligned with the cavity of the first silicon substrate and that is thicker than a second portion of the second silicon substrate that is bonded to the first silicon substrate; and a silicon oxide film interposed between the first silicon substrate and the second silicon substrate.

The cavity SOI substrate according to the present invention can suppress deterioration of flatness of the second silicon substrate in the portion oppositely aligned with the cavity in the first silicon substrate.

### BRIEF DESCRIPTION OF THE DRAWINGS

FIG. 1A is a schematic sectional view illustrating a sectional structure of one example of a cavity SOI substrate according to Embodiment 1 of the present invention.

FIG. 1B is a schematic sectional view illustrating a sectional structure of another example of the cavity SOI substrate according to Embodiment 1 of the present invention.

FIG. 2A is a series of schematic sectional views illustrating individual steps in a first stage of a manufacturing method for the cavity SOI substrate according to Embodiment 1 of the present invention.

FIG. 2B is a series of schematic sectional views illustrating individual steps in a second stage of the manufacturing method for the cavity SOI substrate according to Embodiment 1 of the present invention.

FIG. 3A is a schematic sectional view illustrating a step of forming a resist pattern in a reverse tapered shape on one surface of a second silicon substrate in the manufacturing method for the cavity SOI substrate according to Embodiment 1 of the present invention.

FIG. 3B is a schematic sectional view illustrating a step of, subsequent to the step of FIG. 3A, etching the one surface of the second silicon substrate and forming a projected portion corresponding to the resist pattern.

FIG. 3C is an enlarged sectional view illustrating a shape of an end zone of the projected portion in FIG. 3B.

FIG. 3D is a schematic sectional view illustrating a sectional structure of the second silicon substrate, the sectional structure being obtained after removing the resist pattern in FIG. 3B.

FIG. 4 is a schematic sectional view illustrating a sectional structure of a cavity SOI substrate according to Embodiment 2 of the present invention.

FIG. 5A is a schematic sectional view illustrating a step of forming a mask pattern on the one surface of the second silicon substrate in the manufacturing method for the cavity SOI substrate according to Embodiment 2 of the present invention.

FIG. 5B is a schematic sectional view illustrating a step of, subsequent to the step of FIG. 5A, performing chemical mechanical polishing on the one surface of the second silicon substrate and forming a projected portion corresponding to the mask pattern.

FIG. 5C is an enlarged sectional view illustrating a shape of an end zone 23 of the projected portion in FIG. 5B.

FIG. 6 is a schematic sectional view illustrating a sectional structure of a cavity SOI substrate according to Embodiment 3 of the present invention.

FIG. 7A is a schematic sectional view illustrating a step of bonding the second silicon substrate to a first silicon substrate and then carrying out polishing in a state under application of pressure in the manufacturing method for the cavity SOI substrate according to Embodiment 3 of the present invention.

FIG. 7B is a schematic sectional view of the cavity SOI substrate that is obtained by releasing the pressure after the step of FIG. 7A.

FIG. 8 is a schematic sectional view of a related-art cavity SOI substrate in which a second silicon substrate has substantially the same thickness in both a cavity-aligned portion and a bonded portion.

### DETAILED DESCRIPTION OF THE PREFERRED EMBODIMENTS

According to a first aspect, there is provided a cavity SOI substrate that includes a first silicon substrate having a cavity; a second silicon substrate bonded to the first silicon substrate, wherein the second silicon substrate includes a first portion oppositely aligned with the cavity of the first silicon substrate and that is thicker than a second portion of the second silicon substrate that is bonded to the first silicon substrate; and a silicon oxide film interposed between the first silicon substrate and the second silicon substrate.

According to a second aspect, in the cavity SOI substrate, a surface of the second silicon substrate on a side thereof bonded to the first silicon substrate has a thickness that increases linearly in a direction from the second portion bonded to the first silicon substrate toward the first portion oppositely aligned with the cavity, and that a central region of the first portion oppositely aligned with the cavity includes a zone with a constant thickness.

According to a third aspect, in the cavity SOI substrate, a surface of the second silicon substrate on a side thereof bonded to the first silicon substrate has a curved shape with a thickness that increases in a direction from the second portion bonded to the first silicon substrate toward the first portion oppositely aligned with the cavity, and that a central region of the first portion oppositely aligned with the cavity includes a zone with a constant thickness.

According to a fourth aspect, in the cavity SOI substrate, a surface of the second silicon substrate on a side thereof bonded to the first silicon substrate has a thickness that increases in a direction from the second portion bonded to the first silicon substrate toward a central region of the first portion, the thickness being maximum in the central region of the first portion oppositely aligned with the cavity.

According to a fifth aspect, in the cavity SOI substrate, the second silicon substrate may be curved starting from a boundary region between bonded surfaces of both the first silicon substrate and the second silicon substrate toward a central region of the first portion oppositely aligned with the cavity.

Cavity SOI substrates according to embodiments of the present invention will be described below with reference to the accompanying drawings. It is to be noted that substantially the same members in the drawings are denoted by the same reference signs.

### Embodiment 1

<Cavity SOI Substrate>

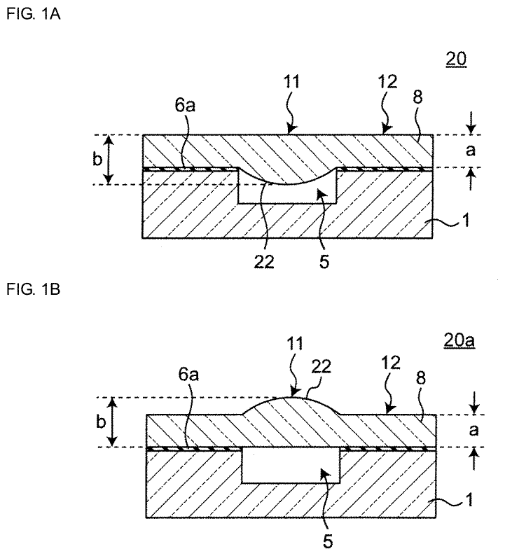

FIG. 1A is a schematic sectional view illustrating a sectional structure of a cavity SOI substrate 20 that is one example of the cavity SOI substrate according to Embodiment 1 of the present invention. FIG. 1B is a schematic sectional view illustrating a sectional structure of a cavity SOI substrate 20a that is another example of the cavity SOI substrate according to Embodiment 1 of the present invention.

The cavity SOI substrates 20 and 20a according to Embodiment 1 of the present invention are each a cavity SOI substrate in which a first silicon substrate 1 having a cavity 5 and a second silicon substrate 8 are bonded to each other with a silicon oxide film 6a interposed therebetween. In the second silicon substrate 8, a cavity-aligned portion 11 oppositely aligned with the cavity 5 in the first silicon substrate 1 is thicker than a bonded portion 12 that is bonded to the first silicon substrate 1. More specifically, a thickness b of the cavity-aligned portion 11 oppositely aligned with the cavity 5 is greater than a thickness a of the bonded portion 12 (a<b). The cavity-aligned portion 11 includes a projected portion 22 with the thickness b being greater than that of a flat surface portion of the second silicon substrate 8.

The cavity-aligned portion 11 is not limited to the case in which the projected portion 22 with the thickness b being greater than in the flat surface portion is present on a lower surface of the second silicon substrate 8 positioned to directly face the cavity 5 (FIG. 1A). Instead, the projected portion 22 may be present on an upper surface of the second silicon substrate 8, the upper surface being positioned not to directly face the cavity 5 (FIG. 1B), or may be present on each of the lower surface and the upper surface (FIG. 6). When the cavity SOI substrates 20 and 20a are used to form MEMS devices, an upper surface of the cavity-aligned portion 11 is preferably flat (FIG. 1A) in a step of forming a movable component on the upper surface side of the cavity-aligned portion 11.

According to the cavity SOI substrates 20 and 20a as described above, in the second silicon substrate 8, the cavity-aligned portion 11 oppositely aligned with the cavity 5 is less susceptible to deformation, and deterioration of flatness can be suppressed.

Members constituting the cavity SOI substrates 20 and 20a will be described below.

<First Silicon Substrate>

The first silicon substrate 1 has a first surface where the cavity 5 is formed, and a second surface positioned in an opposite relation to the first surface. Moreover, the first silicon substrate 1 is bonded to the second silicon substrate 8 with the silicon oxide film 6a interposed therebetween. Another silicon oxide film may be further formed on the second surface of the first silicon substrate 1. As an alternative, a silicon oxide film (for example, a thermally grown oxide film) may be formed on an entire surface of the first silicon substrate 1 including the inside of the cavity 5.

<Second Silicon Substrate>

The second silicon substrate 8 is bonded to the first silicon substrate 1 so as to face the cavity 5 in the first silicon substrate 1. In the second silicon substrate 8, as described above, the cavity-aligned portion 11 oppositely aligned with the cavity 5 in the first silicon substrate 1 is thicker than the bonded portion 12 that is bonded to the first silicon substrate 1. In other words, the thickness b of the cavity-aligned portion 11 is greater than the thickness a of the bonded portion 12 (a<b). The thicknesses a and b are set depending on various conditions.

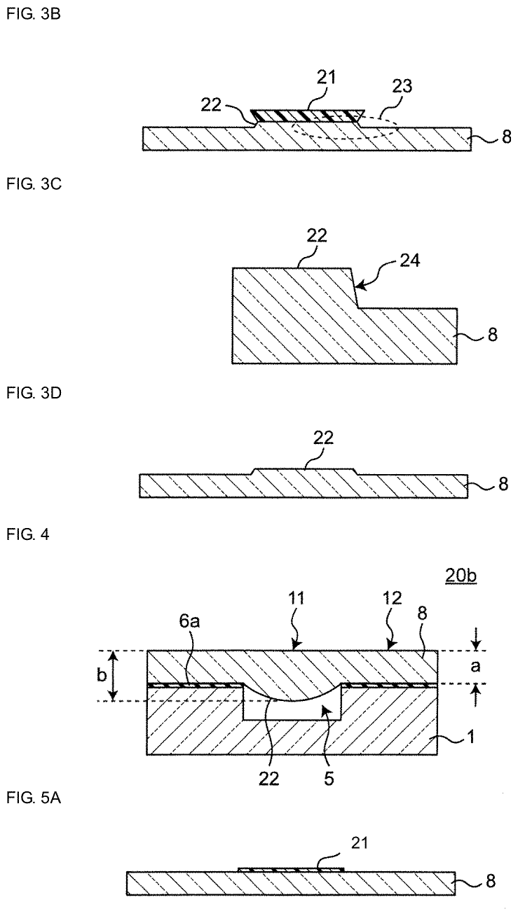

FIG. 3D is a schematic sectional view illustrating a sectional structure of the second silicon substrate 8. As illustrated in FIG. 3D, one surface of the second silicon substrate 8 on a side bonded to the first silicon substrate 1 is formed such that the second silicon substrate 8 has a thickness increasing linearly in a direction from a portion bonded to the first silicon substrate 1 (namely, the bonded portion) toward a central portion, and that a central region of a portion oppositely aligned with the cavity (namely, the cavity-aligned portion) has a constant thickness.

The first silicon substrate 1 and the second silicon substrate 8 may be bonded by, for example, direct bonding with a process called FUSION BONDING described later. A bonding method is not limited to that case.

<Manufacturing Method for Cavity SOI Substrate>

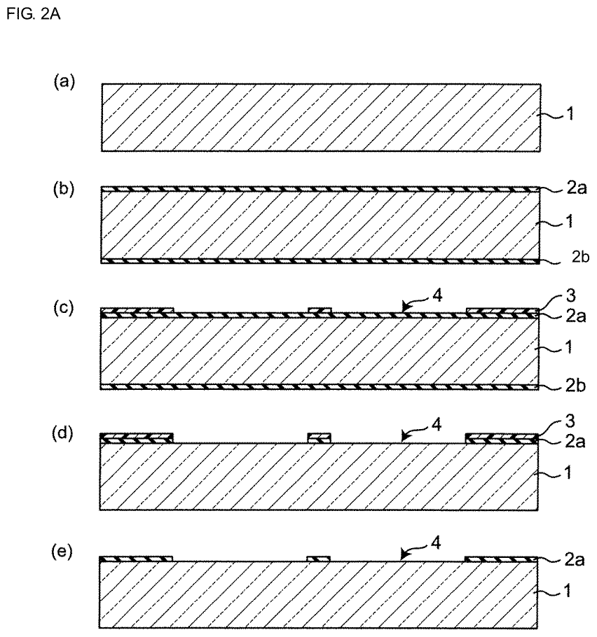

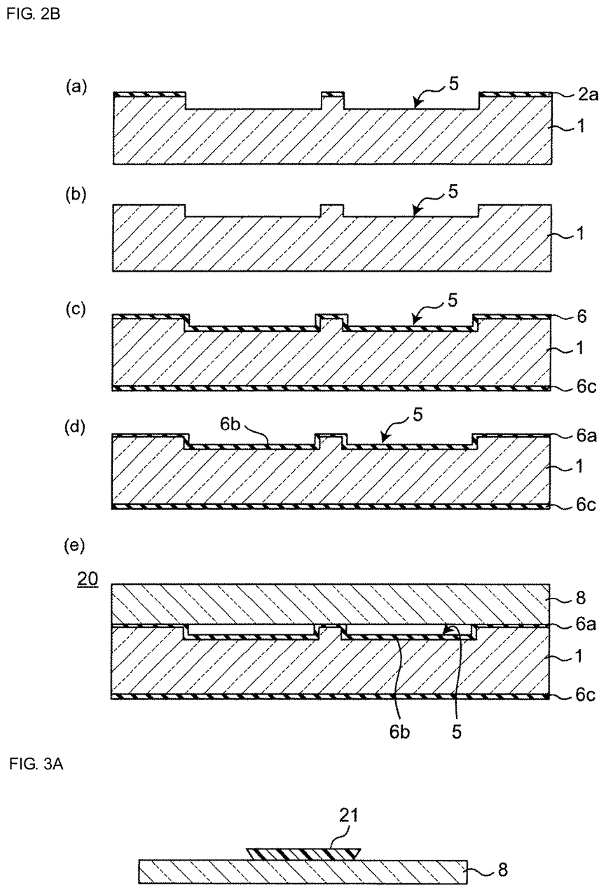

FIGS. 2A and 2B are each a series of schematic sectional views illustrating individual steps of a manufacturing method for the cavity SOI substrate 20 according to Embodiment 1 of the present invention.

(1) The first silicon substrate 1 serving as a base substrate is prepared (FIG. 2A(a)).

(2) The first silicon substrate 1 is thermally oxidized (FIG. 2A(b)). With this step, silicon oxide films 2a and 2b, namely thermally grown oxide films, are formed on the first surface and the second surface of the first silicon substrate 1, respectively.

(3) A resist pattern 3 is formed on the silicon oxide film 2a by utilizing the photolithography technique (FIG. 2A(c)). The resist pattern 3 has an opening 4 in a region where the cavity 5 is to be formed. Thus, the resist pattern 3 is formed to cover the silicon oxide film 2a except for a portion corresponding to the opening 4. On that occasion, the resist pattern 3 can be obtained, for example, by forming a resist, such as a photocurable film, over an entire surface of the silicon oxide film 2a, and then removing the resist positioned in a region where the opening 4 is to be positioned, namely where the cavity 5 is to be formed, with patterning through selective light irradiation.

(4) A portion of the silicon oxide film 2a, the portion being not covered with the resist pattern 3, and the silicon oxide film 2b are removed by wet etching (FIG. 2A(d)). The wet etching may be performed by using hydrogen fluoride or BHF (buffered hydrogen fluoride). Dry etching may be used instead of the wet etching. With this step, only a portion of the silicon oxide film 2a, the portion being covered with the resist pattern 3, is left, and the first silicon substrate 1 is exposed to the outside in the opening 4.

(5) The resist pattern 3 is removed, for example, by ashing or with use of a resist peeling liquid (FIG. 2A(e)).

(6) The cavity 5 is formed in the first surface of the first silicon substrate 1 by DRIE (Deep Reactive-Ion Etching) (FIG. 2B(a)). On that occasion, the silicon oxide film 2a remaining on the first surface of the first silicon substrate 1 serves as a mask, and the cavity 5 is formed in the region of the first surface corresponding to the opening 4.

(7) The silicon oxide film 2a is removed by the wet etching using hydrogen fluoride or BHF (FIG. 2B(b)).

(8) The first silicon substrate 1 is thermally oxidized. With this step, a silicon oxide film 6 to perform the FUSION BONDING is formed on the first silicon substrate 1 (FIG. 2B(c)).

(9) A thickness of the silicon oxide film 6 is adjusted as appropriate, and the second silicon substrate 8 serving as a device substrate is prepared. A preparation step for the second silicon substrate 8 will be described later.

(10) The FUSION BONDING is performed through the steps of washing the first silicon substrate 1 having the cavity 5, which has been obtained through the above-described steps, together with the second silicon substrate 8 as appropriate, carrying out an activation process, and bonding the first silicon substrate 1 having the cavity 5 and the second silicon substrate 8 to each other.

The FUSION BONDING can be implemented through, for example, the following steps.

a) At least one of the first surface of the first silicon substrate 1 and a bonding surface of the second silicon substrate 8 is hydrophilized to form a water film.

b) The first surface of the first silicon substrate 1 and the bonding surface of the second silicon substrate 8 are temporarily bonded by a force of the water film present on the at least one substrate surface.

c) The first silicon substrate 1 and the second silicon substrate 8 are heated in a temporarily bonded state.

d) When reaching about 200° C., water and oxygen are purged out from an interface between the first surface of the first silicon substrate 1 and the bonding surface of the second silicon substrate 8, whereby the bonding at the interface turns to hydrogen bonding. As a result, bonding strength between the first surface of the first silicon substrate 1 and the bonding surface of the second silicon substrate 8 is increased.

e) During a period until reaching about 600° C., voids generating at the interface between the first surface of the first silicon substrate 1 and the bonding surface of the second silicon substrate 8 increases because water and oxygen are purged out.

f) When the temperature is raised to about 1000° C., water and oxygen are diffused into Si and voids are no longer present at the interface between the first surface of the first silicon substrate 1 and the bonding surface of the second silicon substrate 8. Hence the bonding strength between the first surface of the first silicon substrate 1 and the bonding surface of the second silicon substrate 8 is further increased.

In such a manner, the direct bonding between the first silicon substrate 1 and the second silicon substrate 8 can be realized. A method for realizing the direct bonding is not limited to the above-described steps and may be selected as appropriate insofar as the direct bonding can be realized.

(11) Then, an annealing process is performed in an atmosphere containing oxygen at 1000° C. to increase the bonding strength between the first surface of the first silicon substrate 1 and the bonding surface of the second silicon substrate 8, whereby the cavity SOI substrate 20 is obtained (FIG. 2B(e)).

<Preparation Step of Second Silicon Substrate 8>

FIG. 3A is a schematic sectional view illustrating a step of forming a resist pattern 21 in a reverse tapered shape on the one surface of the second silicon substrate 8 in the manufacturing method for the cavity SOI substrate according to Embodiment 1 of the present invention. FIG. 3B is a schematic sectional view illustrating a step of, subsequent to the step of FIG. 3A, etching the one surface of the second silicon substrate 8 and forming the projected portion 22 corresponding to the resist pattern 21. FIG. 3C is an enlarged sectional view illustrating a shape of an end zone 23 of the projected portion 22 in FIG. 3B. FIG. 3D is a schematic sectional view illustrating a sectional structure of the second silicon substrate 8, the sectional structure being obtained after removing the resist pattern 21 in FIG. 3B.

(a) First, the resist pattern 21 in the reverse tapered shape is formed on the one surface of the second silicon substrate 8 (FIG. 3A).

(b) Then, the one surface of the second silicon substrate 8 is processed by dry etching such that a central portion of the second silicon substrate 8, the central portion being oppositely aligned with the cavity 5 in the first silicon substrate 1 is thicker than a peripheral portion thereof (FIG. 3B). At that time, because the shape of the reverse-tapered resist pattern 21 is transferred to the peripheral portion, the second silicon substrate 8 has a sectional shape with a slope 24 in which the thickness of the second silicon substrate 8 increases linearly in the direction toward the central portion from the peripheral portion (FIG. 3C).

The second silicon substrate 8 including the projected portion 22 in the cavity-aligned portion oppositely aligned with the cavity is obtained through the above-described steps (FIG. 3D). The central portion of the second silicon substrate 8 becomes, in each of the cavity SOI substrates 20 and 20a, the cavity-aligned portion 11 that is oppositely aligned with the cavity 5 in the first silicon substrate 1. The peripheral portion of the second silicon substrate 8 becomes, in each of the cavity SOI substrates 20 and 20a, the bonded portion 12 that is bonded to the first silicon substrate 1.

According to the cavity SOI substrates 20 and 20a, in the second silicon substrate 8, the cavity-aligned portion 11 oppositely aligned with the cavity 5 in the first silicon substrate 1 is thicker than the bonded portion 12 that is bonded to the first silicon substrate 1. Therefore, even when a difference in air pressure exists between the inside of the cavity 5 in a vacuum state and the outside of the cavity 5 under an atmospheric pressure, the second silicon substrate 8 is less susceptible to deformation. As a result, deterioration of flatness in each of the cavity SOI (C-SOI) substrates 20 and 20a can be prevented.

Furthermore, since the thickness of the projected portion 22 formed in the central portion of the second silicon substrate 8 is controlled to be constant and shape control is uniformly carried out by the dry etching in the preparation step of the second silicon substrate 8, control of characteristics is easier to perform, and the yield can be increased.

### Embodiment 2

<Cavity SOI Substrate>

FIG. 4 is a schematic sectional view illustrating a sectional structure of a cavity SOI substrate 20b according to Embodiment 2 of the present invention.

Comparing with the cavity SOI substrate 20 according to Embodiment 1, the cavity SOI substrate 20b according to Embodiment 2 of the present invention is different in that the projected portion 22 formed in the cavity-aligned portion 11 has a curved shape.

Stated in another way, the one surface of the second silicon substrate 8 on the side bonded to the first silicon substrate 1 is formed such that the second silicon substrate 8 has a curved shape with a thickness increasing in a direction from a portion bonded to the first silicon substrate 1 toward a central portion, and that a central region of a portion oppositely aligned with the cavity 5 has a constant thickness.

Thus, since, in the second silicon substrate 8, the shape of the projected portion 22 is curved starting from a boundary region between the projected portion 22 and the bonded portion 12, the generation of cracks can be suppressed when the first silicon substrate 1 and the second silicon substrate 8 are bonded to each other, and the yield can be increased. Furthermore, by controlling the thickness and the shape of the second silicon substrate 8 in a combined manner, characteristics can be made easier to control.

<Manufacturing Method for Cavity SOI Substrate>

Comparing with the manufacturing method for the cavity SOI substrate 20 according to Embodiment 1, a manufacturing method for the cavity SOI substrate 20b according to Embodiment 2 of the present invention is different in the preparation step of the second silicon substrate. Other steps are substantially the same as those in the manufacturing method for the cavity SOI substrate according to Embodiment 1, and description of the other steps is omitted.

<Preparation Step of Second Silicon Substrate 8>

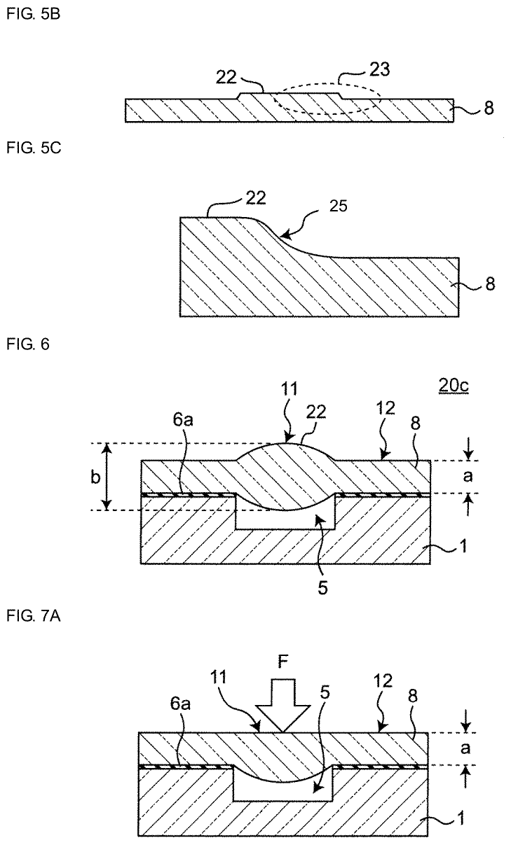

FIG. 5A is a schematic sectional view illustrating a step of forming a mask pattern on the one surface of the second silicon substrate in the manufacturing method for the cavity SOI substrate according to Embodiment 2 of the present invention. FIG. 5B is a schematic sectional view illustrating a step of, subsequent to the step of FIG. 5A, performing chemical mechanical polishing on the one surface of the second silicon substrate and forming a projected portion corresponding to the mask pattern. FIG. 5C is an enlarged sectional view illustrating a shape of an end zone of the projected portion in FIG. 5B.

(a) First, a mask pattern 21 is formed using, for example, a silicon oxide film on the one surface of the second silicon substrate 8 (FIG. 5A).

(b) Then, the one surface of the second silicon substrate 8 on a side where the mask pattern 21 is formed is processed by the chemical mechanical polishing (CMP) such that a central portion of the second silicon substrate 8 is thicker than a peripheral portion thereof (FIG. 5B). At that time, because etching by a chemical reaction progresses together with mechanical machining, the second silicon substrate 8 has a sectional shape with a thickness increasing curvilinearly toward the central portion.

The second silicon substrate 8 with the projected portion 22 having the curved shape 25 and positioned in the cavity-aligned portion oppositely aligned with the cavity is obtained through the above-described steps (FIG. 5C). The central portion of the second silicon substrate 8 becomes, in the cavity SOI substrate 20b, the cavity-aligned portion 11 that is oppositely aligned with the cavity 5 in the first silicon substrate 1. The peripheral portion of the second silicon substrate 8 becomes, in the cavity SOI substrate 20b, the bonded portion 12 that is bonded to the first silicon substrate 1.

According to the cavity SOI substrate 20b including the second silicon substrate 8 obtained as described above, the cavity-aligned portion 11 oppositely aligned with the cavity 5 in the first silicon substrate 1 is thicker than the bonded portion 12 that is bonded to the first silicon substrate 1. Therefore, even when a difference in air pressure exists between the inside of the cavity 5 in a vacuum state and the outside of the cavity 5 under an atmospheric pressure, the second silicon substrate 8 is less susceptible to deformation. As a result, deterioration of flatness of the cavity SOI (C-SOI) substrate 20b can be prevented. Furthermore, since the second silicon substrate 8 is curved starting from a boundary region between bonded surfaces of both the first silicon substrate 1 and the second silicon substrate 8, the generation of cracks can be suppressed when both the substrates are bonded to each other, and the yield can be increased.

### Embodiment 3

<Cavity SOI Substrate>

FIG. 6 is a schematic sectional view illustrating a sectional structure of a cavity SOI substrate 20c according to Embodiment 3 of the present invention.

Comparing with the cavity SOI substrates 20 and 20b according to Embodiments 1 and 2, the cavity SOI substrate 20c according to Embodiment 3 of the present invention is different in that the second silicon substrate 8 includes the projected portion 22 on each of a lower surface of the second silicon substrate 8, the lower surface being positioned to directly face the cavity 5 in the first silicon substrate 1, and an upper surface of the second silicon substrate 8, the upper surface being positioned not to directly face the cavity 5.

Stated in another way, on each of the lower surface of the second silicon substrate 8 on a side bonded to the first silicon substrate 1 and the upper surface of the second silicon substrate 8 on a side not bonded to the first silicon substrate 1, the second silicon substrate 8 includes the projected portion 22 with a thickness increasing in a direction from a portion bonded to the first silicon substrate 1 toward a central portion, the thickness being maximum in a central region of a portion oppositely aligned with the cavity 5.

<Manufacturing Method for Cavity SOI Substrate>

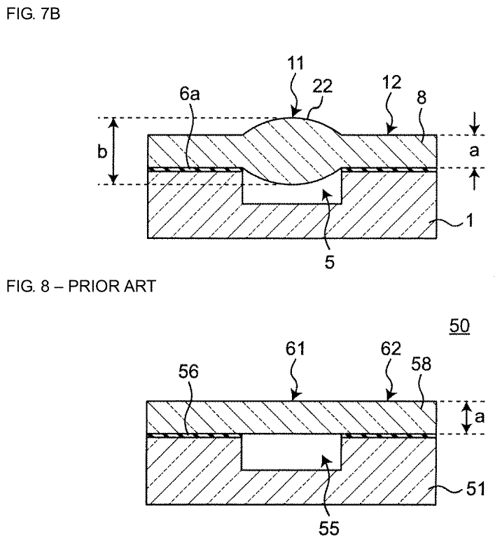

FIG. 7A is a schematic sectional view illustrating a step of bonding the second silicon substrate 8 to the first silicon substrate 1 and then polishing the second silicon substrate in a state under application of pressure in the manufacturing method for the cavity SOI substrate 20c according to Embodiment 3 of the present invention. FIG. 7B is a schematic sectional view of the cavity SOI substrate 20c that is obtained by releasing the pressure after the step of FIG. 7A.

Comparing with the manufacturing methods for the cavity SOI substrates 20 and 20b according to Embodiments 1 and 2, a manufacturing method for the cavity SOI substrate 20c according to Embodiment 3 of the present invention is different in that the projected portion 22 is not previously formed in the preparation step of the second silicon substrate 8. In other words, the manufacturing method for the cavity SOI substrate 20c according to Embodiment 3 is different from the manufacturing methods for the cavity SOI substrates 20 and 20b according to Embodiments 1 and 2 in that, after bonding the first silicon substrate 1 and the second silicon substrate 8 to each other, polishing is carried out in a state under application of pressure. Other steps are substantially the same as those in the manufacturing method for the cavity SOI substrate 20 according to Embodiment 1, and description of the other steps is omitted.

(i) First, the cavity SOI (C-SOI) substrate is fabricated in a similar manner to that in Embodiments 1 and 2.

(ii) Then, the one surface of the second silicon substrate 8 on the side not bonded to the first silicon substrate 1 is polished in a state under application of pressure F (FIG. 7A). The polishing may be carried out by, for example, the chemical mechanical polishing (CMP). On that occasion, the polishing is carried out on condition of, for example, applying the pressure F not lower than the pressure inside the cavity 5 in the first silicon substrate 1. With that polishing, the cavity-aligned portion 11 is flexed and the second silicon substrate 8 can be processed to have a shape with a thickness increasing in the direction from the peripheral portion toward the central portion, the thickness being maximum in the central portion.

(iii) Then, the pressure is released and the cavity SOI substrate 20c is obtained (FIG. 7B). When the pressure is released, part of the upper surface of the second silicon substrate 8 having been pressed downward is caused to project upward with the release of the pressure F, thereby forming the projected portion 22. At the same time, the projected portion 22 remains on the lower surface of the second silicon substrate 8 as well.

Through the above-described steps, the cavity SOI substrate 20c can be obtained in which the second silicon substrate 8 includes the projected portion 22 on each of the lower surface of the second silicon substrate 8 on the side positioned to directly face the cavity 5 in the first silicon substrate 1 and the upper surface of the second silicon substrate 8 on the side positioned not to directly face the cavity 5 in the first silicon substrate 1.

The cavity SOI substrate 20c according to Embodiment 3 can be manufactured by a simpler method than those according to Embodiments 1 and 2. As a result, the manufacturing cost can be reduced.

It is to be noted that the present disclosure may further include appropriate combinations of optionally selected features among the above-described embodiments and/or examples, and that those combinations can also provide similar advantageous effects to those obtained by the above-described embodiments and/or examples.

The cavity SOI substrate according to the present invention can be applied to MEMS devices.

### REFERENCE SIGNS LIST

1 first silicon substrate

2a silicon oxide film

2b silicon oxide film

3 resist pattern

4 opening

5 cavity

6 silicon oxide film

6a silicon oxide film

6b silicon oxide film

6c silicon oxide film

7 resist pattern

8 second silicon substrate

11 cavity-aligned portion

12 bonded portion

20, 20a, 20b, 20c cavity SOI substrate

21 resist pattern

22 projected portion

23 end zone

24 mask pattern

50 cavity SOI substrate

51 first silicon substrate

55 cavity

56 silicon oxide film

58 second silicon substrate

61 cavity-aligned portion

62 bonded portion

1. A cavity SOI substrate comprising:
a first silicon substrate having a cavity; and
a second silicon substrate bonded to the first silicon substrate, wherein the second silicon substrate includes a first portion oppositely aligned with the cavity of the first silicon substrate and that is thicker than a second portion of the second silicon substrate that is bonded to the first silicon substrate; and
a silicon oxide film interposed between the first silicon substrate and the second silicon substrate.

2. The cavity SOI substrate according to claim 1, wherein a surface of the second silicon substrate on a side thereof bonded to the first silicon substrate has a thickness that increases linearly in a direction from the second portion bonded to the first silicon substrate toward the first portion oppositely aligned with the cavity.

3. The cavity SOI substrate according to claim 2, wherein a central region of the first portion oppositely aligned with the cavity includes a zone with a constant thickness.

4. The cavity SOI substrate according to claim 1, wherein a surface of the second silicon substrate on a side thereof bonded to the first silicon substrate has a curved shape with a thickness that increases in a direction from the second portion bonded to the first silicon substrate toward the first portion oppositely aligned with the cavity.

5. The cavity SOI substrate according to claim 4, wherein a central region of the first portion oppositely aligned with the cavity includes a zone with a constant thickness.

6. The cavity SOI substrate according to claim 1, wherein a surface of the second silicon substrate on a side thereof bonded to the first silicon substrate has a thickness that increases in a direction from the second portion bonded to the first silicon substrate toward a central region of the first portion, the thickness being maximum in the central region of the first portion oppositely aligned with the cavity.

7. The cavity SOI substrate according to claim 6, wherein the thickness increases linearly in the direction from the second portion toward the central region of the first portion.

8. The cavity SOI substrate according to claim 7, wherein the central region of the first portion oppositely aligned with the cavity includes a zone with a constant thickness.

9. The cavity SOI substrate according to claim 6, wherein the thickness increases curvilinearly in the direction from the second portion toward the central region of the first portion.

10. The cavity SOI substrate according to claim 9, wherein the central region of the first portion oppositely aligned with the cavity includes a zone with a constant thickness.

11. The cavity SOI substrate according to claim 1, wherein the second silicon substrate is curved starting from a boundary region between bonded surfaces of both the first silicon substrate and the second silicon substrate toward a central region of the first portion oppositely aligned with the cavity.
